(19) United States
(12) Patent Application Publication
(10) Pub. No.: US 2017/0174963 A1
(43) Pub. Date: Jun. 22, 2017

(54) Sealing Compound Housing and Electronic Control Device

(71) Applicant: Conti Temic microelectronic GmbH, Nürnberg (DE)

(72) Inventors: Thomas Riepl, Bad Abbach (DE); Hermann Hämmerl, Ergolding (DE)

(73) Assignee: Conti Temic microelectronic GmbH, Nürnberg (DE)

(21) Appl. No.: 15/452,927

(22) Filed: Mar. 8, 2017

Related U.S. Application Data
(63) Continuation of application No. PCT/EP2015/073024, filed on Oct. 6, 2015.

(30) Foreign Application Priority Data
Oct. 8, 2014 (DE) 10 2014 220 420.8

(51) Int. Cl. C09K 3/10; C09K 15/02; C09K 15/00; H05K 5/04; H05K 5/00; F16J 15/14; C09J 183/08

(52) U.S. Cl. CPC C09K 3/1018; C09K 3/1021; C09K 15/00; C09K 15/02; H05K 5/04; H05K 5/0017; F16J 15/14; C09K 2003/1053; C09K 2200/0685; C09K 2200/065; C09K 2200/0213; C09K 2200/0234

(57) ABSTRACT

The disclosure relates to a sealing compound that can be applied wet and is curable to form an elastic seal. The sealing compound contains a matrix material and a corrosion-inhibiting additive. In addition, a housing having the elastic seal as well as an electronic control device with the housing are disclosed.

### CROSS-REFERENCE TO RELATED APPLICATIONS

This application claims the benefit of PCT Application PCT/EP2015/073024, filed Oct. 6, 2015, which claims priority to German Application DE 10 2014 220 420.8, filed Oct. 8, 2014. The disclosures of the above applications are incorporated herein by reference.

### TECHNICAL FIELD

The present disclosure relates to a sealing compound, to a housing for an electronic control unit, and to an electronic control unit for a motor vehicle.

### BACKGROUND

Housings for electronic control units may have a plurality of housing parts that are connected to one another in a fluid-impervious manner in order to protect a circuit board that is disposed in an interior space of the housing and is populated with electronic components.

Aging effects may be detrimental to the imperviousness of the connection, allowing moisture to penetrate to the interior space and damage the circuit board and the componentry.

### SUMMARY

It is therefore an object of the present disclosure to enable a particularly aging-stable seal. It is a further object of the present disclosure to specify a housing for an electronic control unit that can be given a particularly long-lived seal.

One aspect of the disclosure provides a sealing compound and a housing. In particular, the sealing compound can be applied wet. The sealing compound can be cured to give an elastic seal.

Another aspect of the disclosure provides a housing for an electronic control unit. The housing has a first, metallic housing part and a further housing part. The further housing part may likewise be manufactured of a metallic material. For example, the first housing part is a main housing body composed of an aluminum alloy that includes, in particular, silicon and/or copper. In some examples, the first housing part is a pressure-cast component.

In some implementations, the further housing part may be a housing cover, such as a metal-sheet cover, for example. In some examples, the further housing part is manufactured from a metal sheet—an iron sheet, for example. In some implementations, the further housing part is formed of a metal sheet which is coated at least in the region of the sealing joint. For example, the metal sheet is coated with a layer that comprises or consists of zinc and/or aluminum. In some examples, the layer further includes magnesium, such as a zinc-magnesium alloy.

Formed between the first housing part and the further housing part is a sealing joint which, in the completed state of the housing, is filled with an elastic seal. The elastic seal includes the cured sealing compound. In other words, the gap formed by the sealing joint between the housing parts is sealed, more particularly in a manner impervious to fluid, by means of the elastic seal.

Another aspect of the disclosure provides an electronic control unit for a motor vehicle, including the housing.

The statement that the sealing compound “can be applied wet” is understood to mean that after application to one of the housing parts to be sealed by means of the sealing compound, the sealing compound is plastically deformable, to produce the shape of the elastic seal during the production of the housing. For example, the sealing compound is plastically deformed when the further housing part is pressed onto the first housing part, in order for the sealing joint between the two housing parts to be filled in a manner impervious to fluid. A sealing compound which can be applied wet is occasionally also termed a sealing putty. The elastic seal is also referred to by the skilled person as an FIP seal (“formed in place” seal) or CIP seal (“cured in place” seal). It is, in particular, not a preformed profile seal and also not a coating material.

The sealing compound includes a matrix material. The matrix material may usefully—at any rate in an uncured state of the sealing compound—be plastically deformable and curable to give an elastic material. The matrix material may be an elastomer material. The matrix material includes, for example, a silicone material, as for example a silicone resin, or a polyurethane material, more particularly a synthetic PU resin. An epoxy resin material as well is conceivable as matrix material.

In some examples, the sealing compound additionally includes a corrosion-inhibiting additive. With advantage, owing to the corrosion-inhibiting additive in the sealing compound, there is a particularly low risk of formation, in the region of the sealing joint between the elastic seal and the metallic housing part or metallic housing parts, of corrosion pathways through which unwanted substances—moisture in particular—can penetrate into an interior space of the housing. More particularly, there is a particularly low risk of the seal being undermined by corrosion of the housing part in question at the interface with the metallic housing part(s). With conventional housings, this risk is particularly great, since corrosion is able to progress particularly quickly in the comparatively small gap between seal and metallic housing part.

Utilizing low-corrosion materials for metallic housing parts, or a specific coating of the housing parts before application of the sealing compound, is not absolutely necessary in the case of the present housing—with the advantageous benefit of saving costs—in order to achieve a high level of corrosion resistance on the part of the sealing joint. The cross section of the seal can be kept particularly low.

The corrosion-inhibiting additive is, for example, distributed in the matrix material. The corrosion-inhibiting additive may usefully have been added to the matrix material in the form of a multiplicity of particles—in other words, in particular, in the form of powder or dust. The median of the equivalent diameter of the particles—also referred to by the skilled person as d50 or as average particle size—has a value, for example, of 500 μm or less and/or of 1 μm or more. It is preferably between 2 μm and 100 μm, for example between 5 μm and 60 μm, the limits being included in each case. The equivalent diameter can be determined, for example, based on a polished section of the cured sealing compound.

In some implementations, the particles are bead-shaped, more particularly spherical, and preferably have the same diameter. The statement that the bead-shaped particles have the same diameter is understood presently to mean that the diameters of any two particles differ from one another by less than 10%, preferably by less than 5%. In some examples, the diameter of the bead-shaped particles has a value of 0.1 mm or more, for example 0.4 mm or less. It has, for example, a value of about 0.3 mm. In this way, it is possible by means of the particles to establish an advantageous minimum distance of the housing parts in the region of the sealing joint—i.e., a minimum height of the sealing joint. Accordingly, the risk of inadequate sealing effect or of unsatisfactory long-term stability of the seal because of a seal height which is locally too small is particularly low.

In some implementations, the sealing compound includes a thixotropic agent for uniform distribution of the corrosion-inhibiting additive in the sealing compound. The thixotropic agent may be, for example, silica gel. In this way, the corrosion-inhibiting additive is able to gain access easily to all locations on the interfaces between the housing parts and the sealing compound.

In some examples, the corrosion-inhibiting additive is designed as a sacrificial anode for a corrosion reaction with the metallic housing part or metallic housing parts. For this purpose, in particular, the sealing compound includes particles of a non-noble metal as corrosion-inhibiting additive. With advantage, instead of the respective housing part, the corrosion-inhibiting additive gives off electrons and is oxidized. The matrix material in this case is able to remain in consistently sealing contact with the housing part. The risk of oxidation of housing material and hence of the formation of a gap between the housing part and the matrix material is particularly low.

The sealing compound may include zinc particles as corrosion-inhibiting additive. Additives of the sealing compound that are designed as a sacrificial anode may alternatively or additionally include or consist of at least one of the following materials: Be, Mg, Ca, a lanthanoid such as Sc or Y or La, an actinoid such as Ac, Ti, Zr, Hf, V, Nb, Ta, Cr, Mn, Zn, Cd, Al, Ga, In, Ti, Pb. These materials are highly suitable as sacrificial anode in the case, for example, of a housing part including iron. In some examples, the corrosion-inhibiting additive is designed to bind intermediate products of a corrosion reaction. The intermediate products may be, for example, Fe3+ or OH— or FeOOH. Fe3+, for example, may be bound by an anionic corrosion-inhibiting additive to form a salt of low solubility. OH—, for example, may be bound by a cationic corrosion-inhibiting additive. In some examples, the sealing compound includes zinc phosphate particles as corrosion-inhibiting additive.

In some implementations, the sealing compound includes particles of a pH-buffering material as corrosion-inhibiting additive. In this way, with advantage, at least one housing part can be passivated—especially if it is formed of an aluminum alloy—or the reaction rate of the corrosion reaction is particularly low.

The corrosion-inhibiting additive is formed, for example, by a mixture of sodium dihydrogenphosphate with disodium hydrogenphosphate or with sodium hydroxide solution. The additive in that case is, for example, a phosphate buffer. In this way, in particular, a mandated pH value, in the 6-8 pH range, for example, can be achieved. Alternatively, the corrosion-inhibiting additive may be a barbital-acetate buffer of Michaelis, an acetic acid-acetate buffer, a carbonic acid-silicate buffer, 2-(N-morpholino)ethanesulfonic acid, a carbonic acid-bicarbonate system, 4-(2-hydroxyethyl)-1-piperazineethanesulfonic acid, tris(hydroxymethyl)aminomethane, 4-(2-hydroxyethyl)piperazine-1-propanesulfonic acid, an ammonia buffer, a citric acid buffer or a citrate buffer.

In some implementations, the metallic housing part is formed, at least in the region of the sealing joint, of a first metallic material, and the sealing compound includes particles of a second metallic material as corrosion-inhibiting additive, the electronegativity of the second metallic material being greater than that of the first metallic material. In some examples, the further housing part, at least in the region of the sealing joint, is formed of the first metallic material or of a further metallic material, the electronegativity of the second metallic material being greater than that of the further metallic material. With an additive of this kind it is possible—in particular by means of a substitution reaction—for atoms of the metallic housing parts to be replaced, allowing a coating of high corrosion resistance to form in the region of the interfaces between seal and the respective housing part.

The corrosion-inhibiting additive may have, for example, an electronegativity that is greater than 1.83. In some examples, it is greater than 1.9. In these cases, it is greater than the electronegativity of the materials specified above for the further housing part or for the first housing part, respectively.

The electronegativity of the corrosion-inhibiting additive may usefully be less than 2.6. In this way, the additive is particularly stable chemically.

The corrosion-inhibiting additive may include particles which include or consist of silver and/or nickel, examples being silver particles and/or particles of a silver salt and/or nickel particles and/or particles of a nickel salt. Further materials with suitable electronegativity of which the additive may include or consist of one or more of are as follows: Mo, W, Ru, Os, Rh, Ir, Pd, Pt, Au, B, Ge, Sn, P, As, Sb, S, Se, Te, Po, At.

In some examples, the sealing compound includes two or more different corrosion-inhibiting additives of those described above—for example, an additive designed as a sacrificial anode, and a material designed as a pH buffer. As a result of the different modes of action, it is possible to reduce the risk of corrosion pathways forming in the region of the sealing joint, in a particularly effective way.

In some implementations, the volume fraction of the corrosion-inhibiting additive as a proportion of the volume of the sealing compound is greater than or equal to 10%. In this way, satisfactory inhibition of corrosion may be achieved. In some examples, the volume fraction is less than or equal to 70%, more particularly less than or equal to 50%. In this way, there is particularly low risk of the additive giving rise to leakage pathways which penetrate the elastic seal. A volume fraction of 70% corresponds here, in particular, to the percolation limit.

For the inhibition of corrosion, it is advantageous if the sealing compound has high electron mobility and/or ion mobility. If the matrix material, for example, is a silicone material, satisfactory ion mobility may be achieved through the hygroscopic properties of the matrix material. In some examples, the sealing compound includes a plasticizer, such as a heavy metal, for example. As such, it is possible to achieve a low degree of crosslinking of the cured sealing compound and/or a low glass transition temperature of the sealing compound, with advantageous consequences for the electron and/or ion mobility. Alternatively or additionally, the chain length of the elastomers in the matrix material may be selected appropriately for this purpose.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a schematic sectional representation of a detail of a conventional housing,

FIG. 2 shows a schematic sectional representation of a detail of a housing for a control unit according to a first example,

FIG. 3 shows a schematic sectional representation of a detail of a housing for a control unit according to a second example, and

FIG. 4 shows a schematic sectional representation of a detail of a housing for a control unit according to a third example.

Like reference symbols in the various drawings indicate like elements.

### DETAILED DESCRIPTION

Elements which are the same, which are of the same kind or which have the same effect are given the same reference symbols in the figures. In certain figures, individual reference symbols may be omitted in order to improve clarity. The figures and the size ratios of the elements shown in the figures to one another should not be considered as being to scale. Instead, for improved representation and/or for greater ease of understanding, individual elements may be shown with exaggerated size.

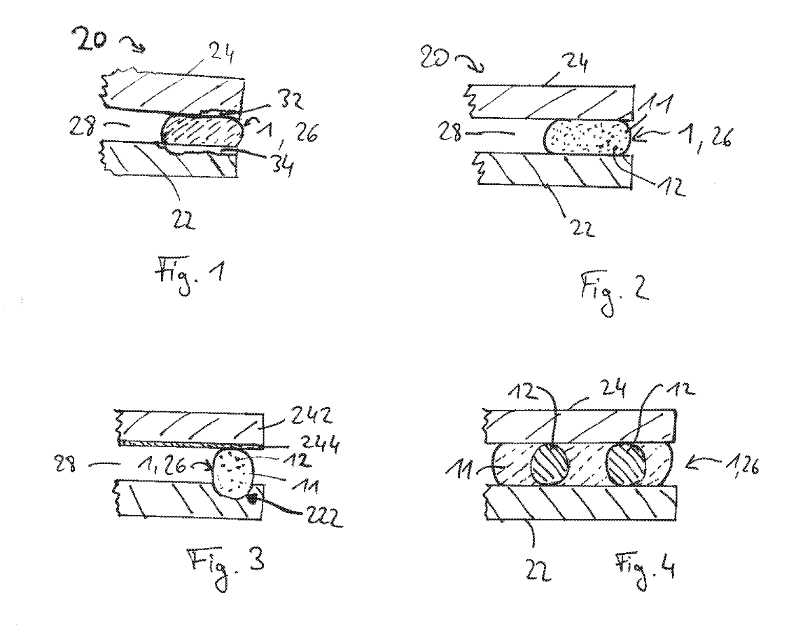

FIG. 1 shows a housing 20 of an electronic control unit with a conventional elastic seal 1, which is disposed in a sealing joint 26 between a first metallic housing part 22 and a further metallic housing part 24. By means of the seal 1 extending along the sealing joint 26, an interior space 28 of the housing 20 is sealed with respect, for example, to penetrating moisture.

Over the lifetime of the control unit, the metallic housing parts 22, 24 may suffer corrosion. In that case, corrosion pathways 32, 34 may form, which undermine the seal 1. For instance, moisture may penetrate through the sealing joint 26 into the interior space 28 of the housing (see, for example, the corrosion pathway 34 in FIG. 1). The penetrating moisture may adversely affect the functional capacity of the control unit.

FIG. 2 shows a schematic sectional view of a detail of a housing 20 according to the disclosure. More precisely, FIG. 2 shows a marginal region of the housing 20. In some examples, the housing 20 is a housing 20 of an electronic control unit, such as of a motor vehicle control unit, for example. The control unit is, for example, an engine control unit.

The housing 20 has a first, metallic housing part 22. This part is, for example, a pressure casting made of an aluminum alloy, more particularly of an alloy familiar to the skilled person as AlSiCu. The first housing part is, for example, a main housing body into which a circuit board populated with electronic components can be inserted—and, in the completed control unit, is inserted.

The housing 20 has a further housing part 24. The further housing part 24, for example, is a cover that seals an assembly aperture in the first housing part 22. In the present case, the further housing part 24 is formed from an iron sheet, by means of embossing, deep drawing or the like, for example.

The further housing part 24 is mounted in the region of the assembly aperture onto the first housing part 22 in such a way that a sealing joint 26 is formed along a peripheral marginal region, this sealing joint 26 producing a fluid-impervious connection between the housing parts 22, 24.

The fluid-impervious connection is obtained by means of an elastic seal 1 which is disposed in the sealing joint 26 in a gap-filling manner, and which therefore borders both the first housing part 22 and the further housing part 24 in order to seal the sealing joint 26. By means of the elastic seal 1, an interior space 28 in the housing 20 is given fluid-impervious closure with respect to the surroundings of the housing 20.

To produce the elastic seal 1, a sealing compound is applied wet to one of the housing parts 22, 24—in the form of a sealing bead, for example—and subsequently the other housing part 22, 24 is pressed onto the sealing compound. In this process, the sealing compound becomes plastically deformed and thus acquires its ultimate form. The sealing compound is subsequently cured to give the elastic seal 1. For this purpose, depending on the material involved, the sealing compound may be subjected, for example, to light, such as UV light, or to heat.

In some examples, the sealing compound—and hence also the elastic seal 1 after the curing of the sealing compound—includes a silicone material or a polyurethane material as matrix material 11. In the case of polyurethane material, for example, a heavy metal plasticizer may have been added to the matrix material 11.

Embedded into the matrix material are zinc particles with a volume fraction of 10% or more, such as of 30%, for example, as corrosion-inhibiting additive 12. The sealing compound may further include silica gel as thixotropic agent in order to distribute the zinc particles uniformly within the silicone material.

Because of moisture in the region of the sealing joint 26, for example, there may be a corrosion reaction with the metallic housing parts 22, 24. In that case, the zinc particles present as corrosion-inhibiting additive 12 in the seal 1 act as sacrificial anodes, which give up electrons and in the process are oxidized. The giving-up of electrons by the housing parts 22, 24 is thereby advantageously reduced or prevented entirely in the region of the sealing joint 26, meaning that at that location the housing parts 22, 24 do not undergo corrosion. The volume fraction of the corrosion-inhibiting additive 12 is below the percolation limit, and so, even if the additive is corroded, a reliably sealing contact between the seal 1 and the housing parts 22, 24 is ensured by means of the matrix material 11. The risk of moisture penetrating into the interior space 28 of the housing 20 through the sealing joint 26 is therefore particularly low.

Instead of the zinc particles or in addition to them, the sealing compound may have a different corrosion-inhibiting additive 12 selected from those described earlier on above.

FIG. 3 shows a schematic sectional representation of a marginal section of a housing 20 according to a second example. The housing 20 of the second example corresponds essentially to that of the first example shown in FIG. 2.

As shown in FIG. 3, however, the further housing part 24 has a main body 242 formed of an iron sheet. This body is provided, on its side facing the sealing joint 26, with a coating 244. In the present case, the coating 244 is formed of a zinc layer or of a zinc-magnesium layer, which is applied on the main body 242. By means of the coating 244, corrosion protection of the further housing part 24 can be achieved even at locations not covered by the seal 1. Alternatively or additionally, the main body 242 may have been provided with the coating 244 on its side facing away from the sealing joint 26.

Moreover, the first housing part 22 is provided with a groove 222 extending along the sealing joint 26. At production, the sealing compound is applied, preferably as a sealing bead, along the groove 222 to the first housing part 22. In this case, by means of the groove 222, the sealing compound can be positioned with particular accuracy.

FIG. 4 shows a schematic sectional representation of a marginal section of a housing 20 according to a third example. The housing 20 of the third example corresponds essentially to that of the first example shown in FIG. 2.

As shown in FIG. 4, however, spherical zinc particles, rather than zinc dust, have been added as corrosion-inhibiting additive 12 to the matrix material 11. All particles have the same diameter of 0.3 mm.

The spherical zinc particles set the minimum height of the sealing joint 26. For this purpose, at production, the housing parts 22, 24 are pressed against one another—with plastic deformation of the sealing compound applied to at least one of the housing parts 22, 24—until the zinc particles make contact with both the first housing part 22 and the second housing part 24. The sealing compound is subsequently cured to give the seal 1.

The description using examples does not confine the invention to these examples. Instead, the invention encompasses every new feature and also every combination of features, including in particular every combination of features in the examples and the claims.

What is claimed is:

1. A sealing compound that can be applied wet and can be cured to give an elastic seal, wherein the sealing compound comprises a matrix material and a corrosion-inhibiting additive.

2. The sealing compound of claim 1, wherein the matrix material comprises a silicone material or a polyurethane material.

3. The sealing compound of claim 1, wherein the corrosion-inhibiting additive has been added to the matrix material in the form of a multiplicity of particles.

4. The sealing compound of claim 3, wherein the particles are bead-shaped.

5. The sealing compound of claim 4, wherein the particles have the same diameter and the diameter has a value of 0.1 mm or more and of 0.4 mm or less.

6. The sealing compound of claim 1, further comprising a thixotropic agent for uniform distribution of the corrosion-inhibiting additive in the sealing compound.

7. The sealing compound of claim 1, wherein the corrosion-inhibiting additive is designed as a sacrificial anode.

8. The sealing compound of claim 1, wherein the corrosion-inhibiting additive comprises zinc particles.

9. The sealing compound of claim 1, wherein the corrosion-inhibiting additive is designed to bind intermediate products of a corrosion reaction.

10. The sealing compound of claim 1, wherein the corrosion-inhibiting additive comprises zinc phosphate particles.

11. The sealing compound of claim 1, wherein the corrosion-inhibiting additive comprises particles of a pH-buffering material.

12. A housing for an electronic control unit, that housing having a metallic housing part and a further housing part, there being formed, between the metallic housing part and the further housing part, a sealing joint filled with an elastic seal composed of a cured sealing compound, the cured sealing compound can be applied wet and can be cured to give an elastic seal, wherein the sealing compound comprises a matrix material and a corrosion-inhibiting additive.

13. The housing of claim 12, wherein the metallic housing part is formed at least in a region of the sealing joint from a first metallic material, and the sealing compound comprises particles of a second metallic material as corrosion-inhibiting additive, an electronegativity of the second metallic material being greater than that of the first metallic material.

14. The housing of claim 13, wherein the first metallic material is an aluminum alloy comprising silicon and copper.

15. The housing of claim 12, wherein the further housing part is formed of a metal sheet that has been coated.

16. The housing of claim 15, wherein the metal sheet is an iron sheet.

17. The housing of claim 12, wherein the corrosion-inhibiting additive has been added to the matrix material in the form of a multiplicity of bead-shaped particles of which two or more contact both the metallic housing part and the further housing part to establish a minimum height of the sealing joint.
